(19) United States
(12) Patent Application Publication
(10) Pub. No.: US 2008/0049804 A1
(43) Pub. Date: Feb. 28, 2008

(54) Semiconductor laser diode with a mesa stripe buried by a current blocking layer made of un-doped semiconductor grown at a low temperature and a method for producing the same

(75) Inventor: Jun-ichi Hashimoto, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: SUMITOMO ELECTRIC INDUSTRIES, LTD.

(21) Appl. No.: 11/889,613

(22) Filed: Aug. 15, 2007

(30) Foreign Application Priority Data
Aug. 25, 2006 (JP) 2006-229436

(51) Int. Cl. H01S 5/227; H01L 33/00

(52) U.S. Cl. 372/45.013; 438/39; 257/E33.049

(57) ABSTRACT

The present invention provides a semiconductor laser diode that has the buried mesa stripe and a current blocking layer without involving any pn-junction. The laser diode includes a lower cladding layer, an active region and an upper cladding layer on the GaAs substrate in this order. The mesa stripe, buried with the current blocking layer, includes the first portion of the upper cladding layer in addition to the active region. The current blocking layer of the invention is made of one of un-doped GaInP and un-doped AlGaInP grown at a relatively low temperature below 600° C. and shows high resistivity greater than 10⁵ Ω·cm for the bias voltage below 5 V.

### CROSS REFERENCE TO RELATED APPLICATIONS

This application closely relates to the application by the same inventor and the same assignee, titled by “Semiconductor laser diode with a ridge structure buried by a current blocking layer made of un-doped semiconductor grown at a low temperature and a method for producing the same”, which is incorporated herein by reference.

### BACKGROUND OF THE INVENTION

1. Field of the Invention

The present invention related to a semiconductor optical device, in particular, the invention relates to a semiconductor laser diode with a buried mesa stripe.

2. Related Prior Art

The buried hetero-structure (hereafter denoted as BH) is well known in a field of the semiconductor laser diode, where the active layer with adjacent layers are etched with a width about 1 μm to form a mesa stripe and this mesa stripe is buried by the current blocking layer. The BH structure may effectively confine both the light and the carriers within the mesa stripe by the current blocking layer provided in both sides of the stripe, accordingly, the efficiency of the stimulated emission from the device may increase, which lowers the threshold current and enhances the slope efficiency of the laser diode.

Conventional current blocking layer applied to the BH structure may be roughly sorted into two groups, one of which is a type with a semiconductor material having a pn-junction therein and the other is a type with a semi-insulating semiconductor material. The former may block the current by the reversely biased pn-junction at the practical operation of the device, while, the device increases the parasitic capacitance in the current blocking layer due to the pn-junction, whereby the device is hard to operate at higher modulation frequencies. On the other hand, the device with the current blocking layer of the latter type may show superior performance in the high speed operation because of no pn-junction in the current blocking layer. Accordingly, applications requesting high speed operation such as optical communication system apply the laser diode with the latter type of the current blocking layer. Japanese Patent Applications published as JP-2001-298240A, JP-H09-214045A and JP-H11-186666 have disclosed such laser diodes with the semi-insulating current blocking layer formed on the InP substrate.

In these laser diode disclosed in references above, the current blocking layer with high resistance is made of InP doped with iron (Fe) that shows a substantially semi-insulating characteristic. Iron doped within InP becomes a deep level within the energy band gap that behaves as a trap center for free carriers within the bands. Thus, the InP doped with Fe shows the high resistance.

In another application, semiconductor lasers formed on the GaAs substrate become quite popular, for example, consumer equipments such as CD player and DVD driver applies the laser diode based on the GaAs materials. These laser diodes are also necessary to provide the current blocking layer with high resistance to make the operational speed thereof faster and to enhance the emission efficiency. However, a semiconductor material with the substantially semi-insulating characteristic like the Fe-doped InP, which is applicable to the current blocking layer of the laser diode, has been unknown for the GaAs based device. Although the GaAs based laser diode with the current blocking layer using the reversely biased pn-junction has been well known, such current blocking layer with the pn-junction causes the less operability in high modulation frequencies because of the parasitic capacitance due to the pn-junction.

Thus, the present invention is to provide a laser diode with the BH structure including the current blocking layer that shows high resistance without degrading the high speed operation.

### SUMMARY OF THE INVENTION

An aspect of the present invention relates to a structure of a semiconductor optical device that includes a mesa stripe structure and a current blocking layer provided on a GaAs substrate with a first conduction type. The mesa stripe includes an active region and a first portion of an upper cladding layer with a second conduction type. The active region is put between the first portion of the upper cladding layer and the GaAs substrate. The current blocking layer is provided on both sides of the mesa stripe so as to bury the mesa stripe. In the present invention, the current blocking layer is made of un-doped group III-V compound semiconductor material. The current blocking layer of the invention may be one of un-doped GaInP or AlGaInP and may show the resistivity greater than 10⁵ Ω·cm.

The active region of the invention may include a well layer made of GaInNAs, a barrier layer made of GaAs, and another well layer made of GaInNAs, wherein these two GaInNAs well layers put the GaAs barrier layer therebetween. The optical device of the invention may further include optical confinement layers, one of which is below and in contact to the GaInNAs well layer and the other of which is on and in contact to the other GaInNAs well layer. Thus, these two optical confinement layers put two GaInNAs well layers and GaAs barrier layer therebetween.

The optical device of the invention may further include lower cladding layer with the first conduction type between the active region and the GaAs substrate, and a second portion of the upper cladding layer with the second conduction type on the mesa stripe and on the current blocking layer.

Another aspect of the present invention relates to a method to produce a semiconductor optical device formed on a GaAs substrate. The method comprises steps of: (a) growing a series of semiconductor layers including a lower cladding layer, an active region, and a first portion of an upper cladding layer; (b) forming a mesa stripe including the active region and the first portion of the upper cladding layer; (c) selectively growing a current blocking layer in both sides of the mesa stripe so as to bury the mesa stripe; and (d) growing a second portion of the upper cladding layer on the mesa stripe and the current blocking layer. A feature of the method is that the current blocking layer may be made of one of un-doped GaInP or un-doped AlGaInP grown at low temperatures from 500° C. to 600° C. Because the current blocking layer is thus formed, the resistivity thereof becomes greater than 10⁵ Ωcm, which is enough high to be applicable for the current blocking layer. The semiconductor optical device may enhance the emission efficiency without degrading the operation speed because of no pn-junction in the current blocking layer.

### BRIEF DESCRIPTION OF DRAWINGS

FIG. 1 is a cross section of a semiconductor optical device according to the first embodiment of the invention;

FIG. 2A shows the resistivity with respect to the applied bias for the specimen including the un-doped GaInP grown at 500° C., and FIG. 2B shows the resistivity for the specimen including the un-doped GaInP grown at 550° C.;

FIG. 3 is an I-L characteristic calculated for the device of the first embodiment shown in FIG. 1;

FIGS. 4A to 4E show the process for manufacturing the optical device of the first embodiment shown in FIG. 1; and

FIG. 5 is a cross section of another optical device according to the second embodiment of the invention.

### DESCRIPTION OF PREFERRED EMBODIMENTS

Subjects of the present invention will be easily understood by referring to accompanying drawings exemplarily illustrated and to the description hereafter. Next, preferred embodiments of the semiconductor laser diode with the buried hetero-structure according to the present invention will be described. In the explanation of the drawings, the same numerals or the same symbols will refer to the same elements without overlapping explanations.

### First Embodiment

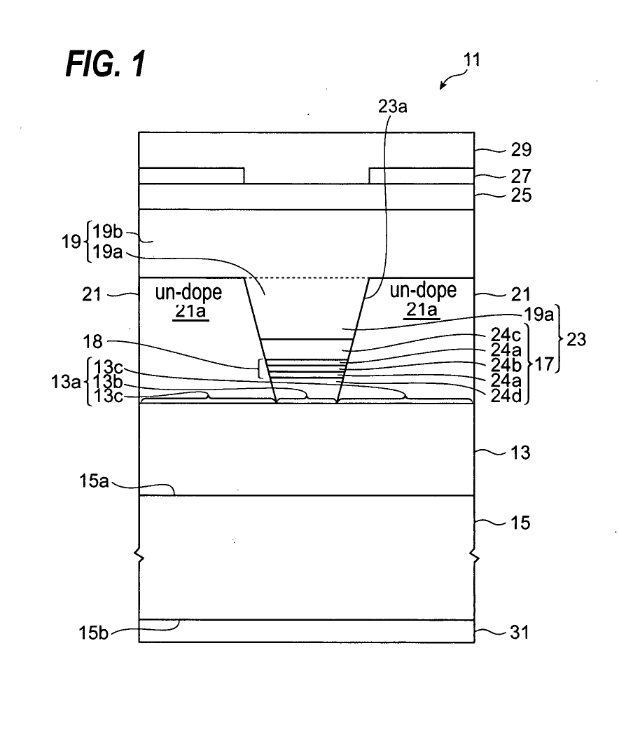

FIG. 1 is a cross section showing a semiconductor optical device according to the present invention. The device shown in FIG. 1 may be applicable to, for example, the optical communication system using a longer wavelength. The semiconductor device 11 provides a lower cladding layer 13 with the first conduction type on the primary surface 15a of the GaAs substrate 15 with the first conduction type. The lower cladding layer 13 and the first portion of the upper cladding layer 19a with the second conduction type put the active region 17 that emits light therebetween. The active region 17 and the first portion of the upper cladding layer 19a forms a mesa stripe 23. The current blocking layer 21, which is formed on the lower cladding layer 13, buries the mesa stripe 23. The current blocking layer 21 includes a semiconductor layer 21a made of un-doped group III-V compound semiconductor material with high resistance.

The device 11 shown in FIG. 1 provides the current blocking layer 21 made of un-doped semiconductor material whose resistivity is greater by several digits than that of semiconductor materials within the mesa stripe 23, by which the current blocking layer substantially blocks the current from flowing, and accordingly, the current supplied to the device 11 may be confined on the mesa stripe 23. Moreover, the current blocking layer 21 of the present device may be free from the pn-junction, which reduces the parasitic capacitance of the device and enables to be operated in higher modulation frequencies.

The mesa stripe 23 further includes the first portion 19a of the upper cladding layer 19. The lower cladding layer 13 of the device shown in FIG. 1 has a primary surface 13a that includes first and second areas, 13b and 13c, respectively. The active region 17 and the first portion 19a of the upper cladding layer 19 are on the first area 13b of the lower cladding layer 13, while the current blocking layer 21 is on the second area 13c of the lower cladding layer 13.

The active region 17, as shown in FIG. 1, includes two quantum well layers 24a and a barrier layer 24b stacked alternately to each other. The well layers and barrier layers constitute the active layer 18. The configuration of the active layer 18 is not restricted to those shown in FIG. 1, for instance, the bulk active layer, a single quantum well layer, and multiple quantum well layers except for the double quantum well layer shown in FIG. 1 may be applicable to the active layer 18. If possible, the active region 17 may include upper and lower optical confinement layers, 24c and 24d, provided so as to put the active layer 18 therebetween.

The lower optical confinement layer 24d has the band gap energy between that of the lower cladding layer 13 and that of the well layer 24a. Similarly, the upper optical confinement layer 24c has the band gap energy between that of the upper cladding layer 19 and that of the well layer 24a. According to those configurations of the optical confinement layers, 24c and 24d, the electrons and the holes supplied from respective cladding layers, 13 and 19, may be effectively injected into the active layer 18 without being blocked by the optical confinement layers 24c and 24d. Moreover, the lower optical confinement layer 24d has a refractive index between that of the lower cladding layer 13 and that of the quantum well layer 24a, and the upper optical confinement layer 24c also has a refractive index between that of the upper cladding layer 19 and that of the quantum well layer 24a. Thus, both cladding layers, 13 and 19, operates so as to confine the light generated in the active layer 18 in the active layer 18, and the upper and the lower optical confinement layers, 24c and 24d, which strengthens the optical confinement within the active layer 18. Thus, to introduce the optical confinement layers, 24c and 24d, may effectively enhance the optical confinement within the active layer 18 without degrading the carrier injection into the active layer 18, which may improve the oscillation performance and the temperature dependence of the device.

The current blocking layer 21 of the invention may be an un-doped group III-V compound semiconductor material lattice-matched to GaAs, such as GaInP and AlGaInP. The un-doped GaInP or AlGaInP shows a semi-insulating characteristic as described later in this specification and has wider band gap energy. Therefore, such semiconductors for the un-doped current blocking layer may make it possible to enlarge the hetero-barrier between the active region 17 and the current blocking layer 21, which suppresses the leakage of the carrier from the active region 17 to the current blocking layer 21 to strengthen the current confinement into the active region 17. The cladding layer, 13 or 19, may be, for example, AlGaAs, GaInAsP, and AlGaInP in addition to GaInP. The optical confinement layer, 24c or 24d, may be, for example, AlGaAs, AlGaInP, GaInAsP, and GaInP in addition to GaAs. These materials may be grown on the GaAs substrate with quite good quality because these materials are lattice-matched to GaAs. The cladding layer, or the optical confinement layer, made of one of these semiconductor materials, may enlarge the band gap difference between these layers and the active layer, which may strengthen the carrier confinement within the active layer to improve the oscillation performance and the temperature dependence of the device. It is favorable to apply the semiconductor materials without containing aluminum (Al), for instance, GaInP, GaInAsP and GaAs, to the cladding layers 13, 19, and the optical confinement layers 24c, 24d from the viewpoint of the reliability. To apply these semiconductor materials to these layers may escape the device from degrading the crystal quality caused by the oxidization of aluminum.

A semiconductor laser diode, which is a type of the device 11 shown in FIG. 1, provides the un-doped GaInP current blocking layer 21 on both sides 23a of the mesa stripe 23 that includes the active region 17. The un-doped GaInP shows a semi-insulating characteristic; accordingly, the current supplied to the device 11 may concentrate on the mesa stripe 23 without flowing in the current blocking layer 21. The composition of GaInP of the current blocking layer 21 may be so determined that this layer is lattice-matched to GaAs, which enables to grow the layer on the GaAs substrate with good quality. The device 11 provides the well layer 24a made of GaInNAs, but not restricted to this material. When the device formed on the GaAs substrate, another group III-V compound semiconductor material containing gallium (Ga), nitrogen (N) and arsenic (As) may be applicable to the well layer 24a, for instance, GaNAs, GaNAsP, GaInNAsP, GaNAsSb, GaInNAsSb, GaNAsSbP, or GaInNAsSbP, all of which are applicable to the well layer 24a of the laser diode showing an emitting wavelength over 1 μm, for example, in a range from 1 to 1.6 μm.

The upper cladding layer 19 with the second conduction type includes the second portion 19b on the current blocking layer 21 and the first portion 19a of the upper cladding layer 19. The second portion 19b may be made of GaInP with the second conduction type lattice-matched to GaAs. To make the second portion 19b thick may make the first portion 19a thin, whereby the process to form the mesa stripe 23 may shorten the etching time thereof; accordingly, the controllability of the width of the mesa stripe 23 may be improved, which enhances the reproducibility of the mesa width and the uniformity of the mesa width within the wafer on which the device is to be formed. Further, the lowered mesa stripe 23 may shorten the growth time for the current blocking layer 21 to bury the mesa stripe 23, which may prevent (1) the deposition of the poly crystal on the mask to protect the mesa stripe 23 during the growth and (2) the anomalous growth of the semiconductor material at the interface between the mesa stripe 23 and the current blocking layer 21.

On the second portion 19b of the upper cladding layer 19 is provided with the contact layer 25 with the second conduction type, and on this contact layer 25 is provided with, if necessary, the insulating layer 27. Further, on the contact layer 25 and on the insulating layer 27 is provided with the first electrode 29, for instance, the anode electrode, while, on the back surface 15b of the GaAs substrate is provided with the second electrode 31, for instance, the cathode electrode.

The insulating layer 27 provides an opening aligned with the first portion 19a of the cladding layer 19, namely, with the mesa stripe 23. The first electrode 29 may electrically come in contact with the contact layer 25 through this opening, and the current supplied from the electrode 29 is injected into the device confined by this opening. However, the opening is not always necessary to be provided, because the current blocking layer 21 may confine the current injected into the device. Exemplary materials for these layers are GaAs for the contact layer 25, and an dielectric material like SiN and SiO₂ for the insulating layer 27.

The optical device 11 provides the current blocking layer 21 made of un-doped group III-V compound semiconductor showing the high resistance and covering the sides 23a of the mesa stripe 23 so as to bury the stripe 23. Accordingly, the current blocking layer 21 may prevent the current from flowing therethrough due to its high resistance property. Further, the current blocking layer excludes any pn-junction therein, whereby the parasitic capacitance in regions outside the mesa stripe 23 becomes small, which makes it possible for the device to operate at higher modulation frequencies.

Next, the un-doped group III-V material for the current blocking layer 21 will be described in detail. The un-doped material for the current blocking layer 21 may be GaInP or AlGaInP. These materials may be grown by various methods described below and show substantially semi-insulating characteristic. Moreover, these semiconductors have wide band gap energy. Accordingly, to apply these materials to the current blocking layer 21 of the present device may enlarge the hetero-barrier between the current blocking layer 21 and the active region 17, which prevents the carriers from leaking from the active region 17 to the current blocking layer 21, hence, the carrier confinement in the mesa stripe 23 may be strengthened. The resistivity of the un-doped material exceeding 10⁵ Ω·cm is preferable for the current blocking layer 21. In this situation, the resistivity of the current blocking layer 21 may be greater, for instance, a several digits greater, than that of the mesa stripe 23. Therefore, the leak current flowing through the current blocking layer 21 can be suppressed enough, and the current may be confined within the mesa stripe 23 effectively.

The un-doped GaInP with the high resistance may be formed by the low-temperature growth technique, for instance, below 600° C. Such low-temperature growth induces deep levels within the band gap. These deep levels have a function to capture the carriers, such as electrons in the conduction band and the holes in the valence band in the present case, which makes the grown material to be high resistive, or substantially insulating.

The GaInP formed by the low temperature growth was evaluated in the resistivity thereof as follows: a specimen having a p-i-n junction comprising (a) an n-type GaInP with a thickness of 0.5 μm and doped with silicon (Si) by 1×10¹⁷ cm⁻³, (b) an un-doped GaInP with a thickness of 1.5 μm and (c) a p-type GaInP with a thickness of 0.5 μm and doped with zinc (Zn) by 7×10¹⁷ cm⁻³; and a contact layer of a p-type GaAs with a thickness of 0.2 μm and doped with Zn by 1×10¹⁹ cm⁻³ was prepared. These layers were provided on an n-type GaAs substrate. The n-type GaInP behaved as the electron supplying layer, while, the p-type GaInP behaved as the hole supplying layer to the un-doped GaInP layer put between these doped layers. The growth of these layers was carried out by the organic metal vapor phase epitaxy (OMVPE) technique. The growth temperature for the un-doped GaInP was preferable to be between 500 and 600° C.

The p-i-n junction region was formed in the mesa structure with a diameter of about 200 μm, and electrodes were provided on the contact layer and the back surface of the GaAs substrate after the forming of the mesa. The I-V characteristic of thus prepared specimen was measured by applying the forward bias to the pin-junction, and the resistivity of the specimen was calculated from this I-V characteristic.

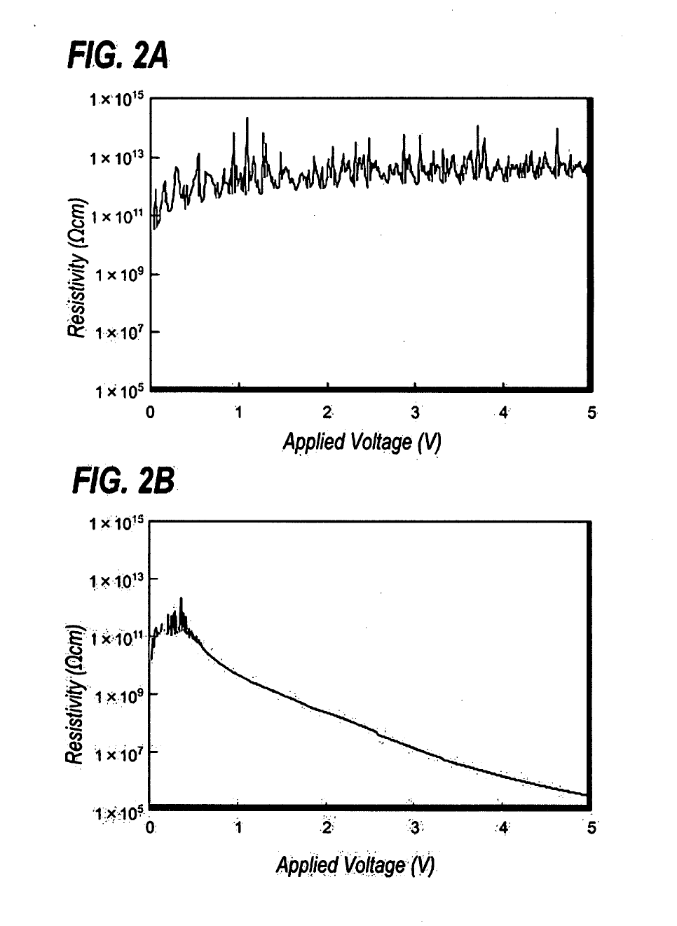

FIG. 2A shows the resistivity to the applied bias for the specimen with the un-doped GaInP grown at 500° C., while, FIG. 2B shows the resistivity for the specimen in which the un-doped GaInP was grown at 550° C. It is understood that quite a high resistivity greater than 10⁵ Ω·cm can be obtained for both specimens under forward biases below 5 V, which is an normal operating bias condition for the laser diode. Moreover, the first specimen in which the un-doped GaInP was grown at 500° C. shows a higher resistivity compared to the other specimen with the un-doped GAInP grown at 550° C.

Thus, FIGS. 2A and 2B indicate that, the un-doped GaInP grown at relatively low temperatures contains a great number of the deep levels behaving as the trapping center for both electrons and holes, and shows the quite high resistivity for both carriers. This is because, if the un-doped GaInP contains the deep levels which can trap only one of carriers, a leak current due to the other carriers not captured by the deep levels becomes substantial and the high resistivity as shown in FIGS. 2A and 2B could be unobtainable.

Thus, the un-doped GaInP grown at low temperatures was verified to behave as a layer with the high resistivity over 10⁵ Ω·cm for both electrons and holes. Because the resistivity of the mesa stripe 23 is generally smaller by several digits than this value, accordingly, the un-doped GaInP grown at the low temperature may be applicable to the current blocking layer 21. Similarly, the high resistivity such as mentioned above may be available in the un-doped AlGaInP grown at low temperatures such between 500 and 600° C.

A semiconductor laser based on the InP substrate often provides the current blocking layer with the high resistance made of Fe-doped InP. To dope irons (Fe) into the InP induces the trapping centers for the electron, whereby the Fe-doped InP behaves as a high resistive layer for the electrons. However, because the Fe-doped InP does not provide a function to capture the holes, the Fe-doped InP is unable to operate as the current blocking layer for the p-type cladding layer where the hole is the majority carrier. The un-doped material, such as GaInP grown at the low temperature, may show the high resistance for both the electron and the hole, accordingly, such material becomes applicable as the current blocking layer for the p-type and the n-type cladding layers, which enhances the flexibility of the current blocking arrangement. In addition, the un-doped material needs no impurity such as Fe and no additional apparatus for doping it, so that it may be easily grown compared to the doped materials such as Fe-doped InP.

When the impurities are doped to obtain a material with the high resistance, such as Fe-doped InP, the inter-diffusion of the impurities between the current blocking layer and the adjacent layers often occurs at the growing process. For example, it is well known that the iron (Fe) contained in the InP current blocking layer easily inter-diffuses with the zinc (Zn) contained in the cladding layer as the p-type dopant. The inter-diffusion of impurities causes the decrease of the resistance and the increase of parasitic capacitance of the current blocking layer. The present current blocking layer may escape from such subject because of its un-doped characteristic.

Exemplary conditions of semiconductor layers and regions of the device 11 are listed below:

TABLE 1
Conditions of each layer

| Layer/Region | Material | thickness | |
|---|---|---|---|
| Substrate 15 | n-type GaAs | 100 | μm |
| lower cladding layer 13 | n-type GaInP | 1.5 | μm |
| active region 17 | | | |
| well layer 24a | un-doped GaInNAs | 7 | nm |
| barrier layer 24b | un-doped GaAs | 8 | nm |
| upper optical confinement layer 24c | un-doped GaAs | 140 | nm |
| lower optical confinement layer 24d | un-doped GaAs | 140 | nm |
| upper cladding layer 19 | | | |
| first portion 19a | p-type GaInP | 0.3 | μm |
| second portion 19b | p-type GaInP | 1.2 | μm |
| current blocking layer 21 | un-doped GaInP | 0.6 | μm |
| contact layer 25 | p-type GaAs | 0.2 | μm |
| insulting layer 27 | dielectric film like | | |
| | SiN and SiO₂ | | |

### This semiconductor optical device 11, which shows a function of the semiconductor laser diode, enables to emit light with emission wavelengths greater than 1 μm, specifically between 1 and 1.6 μm, by the quantum well layer 24a made of GaInNAs.

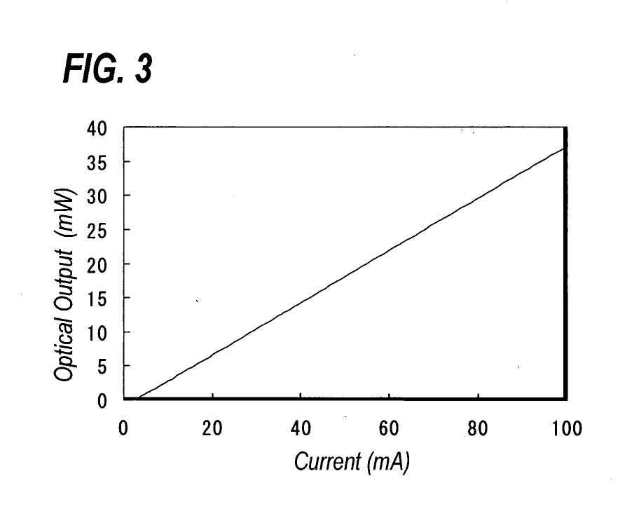

FIG. 3 shows an I-L (current to light) characteristic calculated from the structure shown in FIG. 1. The calculation assumes that the device has the optical cavity, a length of which is 300 μm with un-coated facets defining the optical cavity, and the resistivity of the current blocking layer 21 refers to the result shown in FIG. 2A, which corresponds to the specimen grown at 500° C. The I-L characteristic shows the small threshold current and the good linearity, which demonstrates that the un-doped GaInP current blocking layer grown at a low temperature may effectively confine the carriers in the mesa stripe.

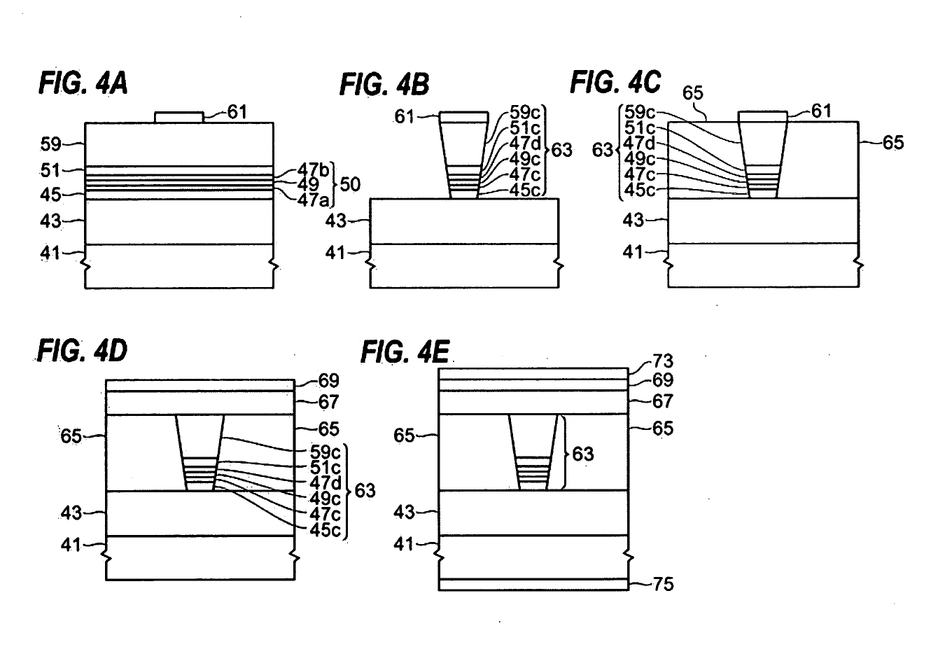

Next, a method for producing the optical device 11 shown in FIG. 1 will be described as referring to FIG. 4. The present process uses the OMVPE technique for the growth of the semiconductor layers. First, an n-type GaAs substrate 41 is prepared. The first epitaxial growth sequentially stacks on the n-type GaAs substrate 41, an n-type GaInP lower cladding layer 43, an un-doped lower optical confinement layer 45, an un-doped GaInNAs quantum well layer 47a, an un-doped GaAs barrier layer 49, an un-doped GaInNAs quantum well layer 47b, an un-doped GaAs upper optical confinement layer 51, and a first portion 59 of the p-type upper cladding layer. The un-doped GaInNAs well layer 47a, the un-doped GaAs barrier layer 49 and the un-doped GaInNAs quantum well layer 47b constitute the active layer 50.

Next, the process forms a mask 61 made of dielectric material for forming the mesa stripe on the first portion 59 of the p-type GaInP upper cladding layer. This mask 61 may be made of SiN or SiO₂. Subsequently, the process etches the un-doped lower optical confinement layer 45, the un-doped GaInNAs well layer 47a, the un-doped GaAs barrier layer 49, the un-doped GaInNAs well layer 47b, the un-doped GaAs upper optical confinement layer 51, and the p-type upper cladding portion 59 by adequate etchants for respective layers to form the mesa stripe 63, as shown in FIG. 4B. Thus, the mesa stripe 63 includes the un-doped GaAs lower optical confinement layer 45c, the un-doped GaInNAs well layer 47c, the un-doped GaAs barrier layer 49c, the un-doped GaInNAs well layer 47d, the un-doped GaAs upper optical confinement layer 51c and the first portion 59c of the p-type GaInP upper cladding layer. The cross section and planar shape of the mesa stripe 63 can be changed depending on the surface direction of the substrate 41 and types of respective etchants for etching the layer.

For example, with the hydrochloric acid, the etching rate of GaInP is much larger than that of the GaAs and GaInNAs, while with the phosphoric acid, the etching rates of GaAs and GaInNAs are much larger than that of the GaInP. Therefore, the GaAs layer under the GaInP layer may be an etching-stop layer for the hydrochloric etchant, while, the GaInP layer under the GaAs or the GaInNAs layer may become an etching-stop layer for the phosphoric etchant.

Specifically, the process first etches the first portion 59 of the p-type GaInP upper cladding layer with hydrochloric acid, then, the GaAs upper optical confinement layer 51 beneath this GaInP layer 59 shows the function of the etching-stop layer. When the GaAs upper optical confinement layer 51 is exposed by the etching, the etching automatically stops as forming the first portion 59. Next, the process etches the GaInNAs well layers, 47a and 47b, the GaAs barrier layer 49, and the GaAs upper and lower optical confinement layers, 51 and 45, with the etchant containing the phosphoric acid. In this second etching, the n-type GaInP lower cladding layer 43 beneath the GaAs lower optical confinement layer 45 behaves as the etching-stop layer. Thus, when the n-type GaInP lower cladding layer 43 is exposed, the second etching automatically stops.

In the present embodiment, even if the etching rate of the first and second etchants, each containing the hydrochloric acid or the phosphoric acid, fluctuates from batch to batch, or within a wafer to be processed, the etching to form the mesa stripe 63 may automatically stop when the lower cladding layer 43 is exposed. Thus, quite a superior performance may be obtained in the reproducibility and the uniformity within the whole wafer for the cross section and the planar shape of the mesa stripe including the dimensions thereof.

In conventional processes for the optical device, an additional etching-stop layer is necessary to be provided beneath the layer 45 to be etched, namely between the lower optical confinement layer 45 and the lower cladding layer 43, to secure the reproducibility and the uniformity of the etching process. However, to add the etching-stop layer inevitably accompanies with an additional hetero-barrier to the adjacent layers, which increases a parasitic resistance, thereby heat generation, and degrades the performance and the reliability of the device. On the other hand, the present optical device provides the lower cladding layer 43 that has the function of the etching-stop layer; therefore, any additional layer is unnecessary to stop the etching.

When the lower optical confinement layer 45 is made of one of GaAs, AlGaAs, or GaInAsP, the lower cladding layer 43 is preferable to be made of GaInP or AlGaInP. For this combination, the lower cladding layer 43 may show the etching-stop function for the etchant containing phosphoric acid, because the etching rate of GaInP and AlGaInP shows far smaller than that of GaAs, AlGaAs and GaInAsP. On the other hand, when the lower optical confinement layer 45 is made one of GaInP or AlGaInP, the lower cladding layer 43 is preferable to be made of AlGaAs or GaInAsP. In this combination, the lower cladding layer 43 made of AlGaAs or GaInAsP may behave as an etching-stop layer for the lower optical confinement layer 45 for the etchant containing hydrochloric acid.

Although the process above described applies the selective etching for forming the mesa stripe 63, it is not restricted to the selective etching. For instance, an etchant containing bromic acid and hydrogen peroxide shows a non-selective etching characteristic for all layers within the mesa stripe 63. In this case, the etching does not stop even when the lower cladding layer 43 is exposed, and a portion of the lower cladding layer 43 may be etched, thus, the mesa stripe 63 does contain a portion of the lower cladding layer 43.

Subsequent to form the mesa stripe 63, the second epitaxial growth is carried out to form the un-doped GaInP current blocking layer 65 as leaving the mask 61 on the topmost layer of the mesa stripe 63, as shown in FIG. 4C. The second growth is preferable, as described previously, to be done at low temperatures. In such a condition, the process grows the un-doped GaInP layer 65 on the n-type GaInP lower cladding layer 43 so as to bury the mesa stripe 63 without growing on the mask 61.

Because the second growth is carried out at a low temperature, for instance, from 500 to 600° C., the process does not degrade the crystal quality of the active layer 50 by the thermal stress during the growth. In particular, the ternary or quaternary group III-V compound semiconductor material containing gallium (Ga), arsenic (As) and nitrogen (N) like GaInNAs in the present active layer is sensitive to thermal stress; accordingly, the current blocking layer grown at a low temperature has a great advantage. After removing the mask 61, the third growth forms the second portion of the p-type GaInP upper cladding layer 67 and the p-type GaAs contact layer 69 on the mesa stripe 63 and the current blocking layer 65, which is illustrated in FIG. 4D.

Finally, the process polishes the back surface of the n-type GaAs substrate 41 to a thickness thereof about 100 μm such that the GaAs substrate 41 may be easily cleaved, as shown in FIG. 4E. To form the anode and cathode electrodes, 73 and 75, completes the laser diode with a type of the buried hetero structure. In advance to the formation of the anode electrode 73, the process may form the insulating layer, which corresponds to the layer 27 in FIG. 1, between the p-type GaAs contact layer 69 and the anode electrode 73 to narrow the region where the current flows. Thus, the optical semiconductor device 11 is completed.

In the buried hetero structure of the present embodiment, the upper cladding layer provides, in addition to the first portion 59c, a second portion 67. Thicker second portion 67 may result in a thinner first portion 59c, whereby the process may form the mesa stripe 63 in the shortened etching time, which enhances not only the controllability of the width of the mesa stripe 63 but also the reproducibility and the uniformity of the dimensions of the cross section and the planar shape of the mesa stripe 63. Moreover, the lowered mesa stripe 63 results in the shortened process time for the growth of the current blocking layer 65, whereby various subjects may be solved, for instance, the deposition of poly crystals on the mask 61 and/or the anomalous growth of the current blocking layer 65 at the boundary between the mesa stripe 63 and the current blocking layer 65.

### Second Embodiment

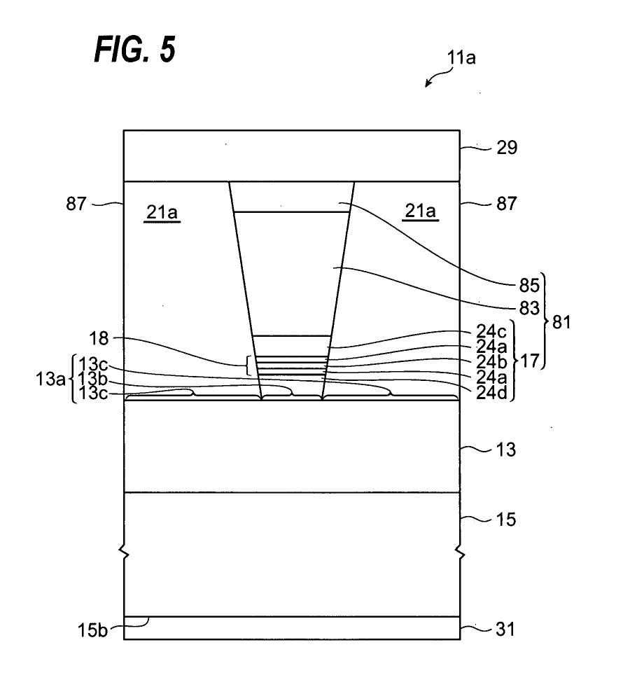

FIG. 5 illustrates a semiconductor optical device according to the second embodiment of the present invention. The optical device 11a shown in FIG. 5 provides, similar to the device 11 of the first embodiment, the lower cladding layer 13 with the first conduction type and the active region 17 on the lower cladding layer 13. These region 17 and layer 13 are provided on the GaAs substrate 15 with the first conduction type. The mesa stripe 81 of the device 11c is provided on the first area 13b of the lower cladding layer 13.

The mesa stripe 81 includes the active region 17, the upper cladding region 83 with the second conduction type and the contact layer 85 also with the second conduction type. The current blocking layer 87 is provided on the second area 13c of the lower cladding layer 13 so as to bury the mesa stripe 81. Similar to the current blocking layer 21 in the first embodiment, the current blocking layer 87 in this embodiment includes layers 21a made of un-doped group III-V compound semiconductor material with high resistance. The device 11a may be completed through the crystal growth less than that of the first embodiment, which may reduce not only the process cost itself but also the thermal stress induced in the active region 17 during the crystal growth. Thus, the structure shown in FIG. 5 is quite applicable to the device with the well layer made of ternary or quaternary group III-V compound semiconductor materials containing gallium (Ga), nitrogen (N) and arsenic (As), which are sensitive to the thermal stress.

In the optical device 11a shown in FIG. 5, the current blocking layer shows the high resistivity, for example, over 10⁵ ∩·cm which is greater than that of the mesa stripe 81 by several digits. Thus, the current supplied from the electrodes is hard to flow in the current blocking layer 87 and concentrates within the mesa stripe 81. Moreover, the current blocking layer 87 does not provide any pn-junction, which reduces the parasitic capacitance and enables the device to be modulated and to operate at higher modulation frequencies.

The device 11a provides the first electrode 29, for instance, the anode electrode, on the contact layer 85 and the current blocking layer 87. The device may provide, if necessary, an insulating layer between the anode electrode 29 and the contact layer 85, and between the anode electrode 29 and the current blocking layer 87, which corresponds to the layer 27 in the device 11 shown in FIG. 1, to narrow the current path and to concentrate the carrier within the mesa stripe 81. In this arrangement, the electrode 29 may electrically come in contact with the contact layer 85 through the opening in the insulating layer. The back surface 15b of the GaAs substrate 15 provides the second electrode 31, for instance, the cathode electrode.

The current blocking layer 87 of the present embodiment, similar to the layer 21 in the first embodiment, may be an un-doped GaInP or AlGaInP grown at low temperatures below 600° C. The GaInP or AlGaInP grown at such a low temperatures has substantially semi-insulating characteristic. The resistivity of these materials may be over 10⁵ Ω·cm as already explained, so that the current blocking layer 87 shows the resistivity greater than that of the mesa stripe 81 by several digits. Accordingly, the current becomes hard to flow in the current blocking layer 87 and concentrates on the mesa stripe 81.

Exemplary conditions of the device 11a are as follows:

TABLE 2
Conditions of each layer in the second embodiment

| Layer/Region | Material | thickness | |
|---|---|---|---|
| Substrate 15 | n-type GaAs | 100 | μm |
| lower cladding layer 13 | n-type GaInP | 1.5 | μm |
| active region 17 | | | |
| well layer 24a | un-doped GaInNAs | 7 | nm |
| barrier layer 24b | un-doped GaAs | 8 | nm |
| upper optical confinement layer 24c | un-doped GaAs | 140 | nm |
| lower optical confinement layer 24d | un-doped GaAs | 140 | nm |
| upper cladding layer 83 | p-type GaInP | 1.5 | μm |
| current blocking layer 87 | un-doped GaInP | 2.0 | μm |
| contact layer 85 | p-type GaAs | 0.2 | μm |

While the present invention has been described with reference to the specific embodiments thereof, it should be understood by those skilled in the art that various changes may be made and equivalents may be substituted without departing from the true spirit and scope of the invention. In addition, embodiments described above exemplarily illustrate a semiconductor laser diode with a Fabry-Perot type. However, the present invention is not restricted to the Fabry-Perot type, and may be applicable to devices with another arrangements, such as a distributed feedback (DFB) laser diode, a light-emitting diode (LED), an optical modulator with an electro-absorption type, an semiconductor optical amplifier, a laser diode with a distributed Bragg reflector (DBR), and a vertical cavity surface emitting laser (VCSEL), and to devices integrating with such various semiconductor devices. Furthermore, embodiments above described provide only two well layers within the active region. However, the optical device according to the present invention may provide single quantum well layer or a multiple quantum well layers. All such modifications are intended to be within the scope of the claims appended hereto.

I claim:

1. A semiconductor optical device, comprising:
a GaAs substrate;
a mesa stripe provided on the GaAs substrate with a first conduction type, the mesa stripe including an active region and a first portion of an upper cladding layer with a second conduction type different from the first conduction type, the active region being put between the GaAs substrate and the first portion of the upper cladding layer; and
a current blocking layer provided on the GaAs substrate, the current blocking layer burying the mesa stripe,
wherein the current blocking layer includes an un-doped group III-V compound semiconductor material.

2. The semiconductor optical device according to claim 1,
wherein the un-doped group III-V compound semiconductor material is one of un-doped GaInP or un-doped AlGaInP.

3. The semiconductor optical device according to claim 1,
wherein resistivity of the un-doped group III-V compound semiconductor material is greater than 10⁵ ∩·cm.

4. The semiconductor optical device according to claim 1,
further comprising a second portion of the upper cladding layer with the second conduction type provided on the mesa stripe and on the current blocking layer.

5. The semiconductor optical device according to claim 4,
further comprising a contact layer with the second conduction type provided on the second portion of the upper cladding layer.

6. The semiconductor optical device according to claim 1,
wherein the active region includes,
a first well layer made of GaInNAs, a barrier layer made of GaAs provided on the first well layer, and a second well layer made of GaInNAs provided on the barrier layer,
wherein the barrier layer is sandwiched by the first well layer and the second well layer.

7. The semiconductor optical device according to claim 6,
wherein the active region further includes,
a lower optical confinement layer made of GaAs beneath the first well layer, and
an upper optical confinement layer made of GaAs on the second well layer.

8. A method for manufacturing a semiconductor laser diode, comprising steps of:
(a) growing a lower cladding layer with the first conduction type, an active region, a first portion of an upper cladding layer with a second conduction type sequentially on a GaAs substrate with the first conduction type;
(b) forming a mesa stripe including the active region and the first portion of the upper cladding layer;
(c) selectively growing an un-doped GaInP current blocking layer on both sides of the mesa stripe at temperatures between 500° C. to 600° C. so as to bury the mesa stripe, and
(d) growing a second portion of the upper cladding layer with the second conduction type on the mesa stripe and on the current blocking layer.

9. The method according to claim 8,
wherein the step for growing the active region includes a step of growing a first well layer made of GaInNAs, a barrier layer made of GaAs and a second well layer made of GaInNAs.

10. The method according to claim 9,
wherein the step for growing the active region further includes steps of,
growing a lower optical confinement layer made of GaAs before the growth of the first well layer, and
growing an upper optical confinement layer made of GaAs after the growth of the second well layer.
